(19) United States
(12) Patent Application Publication
(10) Pub. No.: US 2002/0149121 A1
(43) Pub. Date: Oct. 17, 2002

(54) Base interconnection substrate, manufacturing method thereof, semiconductor device and manfacturing method thereof

(75) Inventors: Taketoshi Shikano, Hyogo (JP); Namiki Moriga, Hyogo (JP); Takehiko Suwa, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki kaisha, Tokyo (JP)

(21) Appl. No.: 09/938,481

(22) Filed: Aug. 27, 2001

(30) Foreign Application Priority Data
Apr. 12, 2001 (JP) 2001-113454

(51) Int. Cl. H01L 23/48

(52) U.S. Cl. 257/787; 257/778

(57) ABSTRACT

A semiconductor device includes a base interconnection substrate having an interconnect portion, an IC chip mounted on the base interconnection substrate, and a mold resin portion encapsulating the IC chip. The base interconnection substrate includes an electrode pad for external connection that is connected to the interconnect portion, and a reinforcing pad for preventing the base interconnection substrate from deforming in a transfer mold process.

### BACKGROUND OF THE INVENTION

1. Field of the Invention

The present invention relates to a base interconnection substrate, a semiconductor device and respective methods of manufacturing the base interconnection substrate and the semiconductor device. In particular, the invention relates to a structure for reinforcing the base interconnection substrate having a mounting plane on which external connection terminals are arranged, a semiconductor device having such a base interconnection substrate, and respective methods of manufacturing the base interconnection substrate and the semiconductor device.

2. Description of the Background Art

A semiconductor device having a BGA (Ball Grid Array) structure has terminals arranged on the entire mounting plane of a package and thus achieves a higher pin count without increase in the package size. Accordingly, semiconductor devices of this type have increasingly become popular in the use where reduction of mounting area is required.

Conventional structures of the BGA package have been designed to uniformly arrange all terminals in terms of reliability as disclosed in Japanese Patent Laying-Open No. 9-64244.

However, with the recent increase in number of electrode pads and decrease in pitch between electrode pads, there may be cases where electrode pads cannot be arranged in the central region for example of a base interconnection substrate due to restriction on the number of interconnections between electrode pads and on the external size of the package.

Further, in terms of signal delay, it may be advantageous to arrange electrode pads in the peripheral region of a package depending on the method of coupling an IC (integrated Circuit) chip and a base interconnection substrate to ensure transfer characteristics.

Accordingly, some package structure includes electrode pads arranged in the peripheral region of a base interconnection substrate and no electrode pad arranged in the central region of the base substrate.

This type of semiconductor device has a problem as discussed below. FIG. 3 shows a transfer mold step in a manufacturing process of a conventional semiconductor device.

Referring to FIG. 3, in a cavity 12 formed between molds 1 1, a resin frame 19 is placed having an IC chip 3 mounted thereon via a die bonding material 2, and IC chip in this state is encapsulated by resin.

As shown in FIG. 3, resin frame 19 is connected to IC chip 3 via a Au wire 5 and has an electrode pad 7, a through hole 9, a solder resist 10 and a conductor portion 17. After the resin encapsulation as discussed above, resin frame 19 is divided to form a base interconnection substrate.

However, no electrode pad 7 is present in the central region of resin frame 19 as shown in FIG. 3 and consequently there is a gap 13 under the central region of resin frame 19 at the time of resin encapsulation, i.e., at the transfer mold step.

At the transfer mold step, mold resin has an injection pressure of approximately 6.9±0.5 MPa which is exerted on resin frame 19 and IC chip 3 from above. Consequently, the injection pressure causes deformation of resin frame 19 due to the presence of such a gap 13. Then, a stress due to local distortion is generated on IC chip 3 resulting in a problem of damage or breakdown of the chip.

### SUMMARY OF THE INVENTION

The present invention has been made to overcome the problem as discussed above. One object of the present invention is to prevent damage to a semiconductor chip in a transfer mold process that is mounted on a base interconnection substrate of a semiconductor device.

A semiconductor device according to the present invention includes a base interconnection substrate having an interconnect portion, an electrode pad for external connection formed on a first surface of the base interconnection substrate and connected to the interconnect portion, a reinforcing member formed on the first surface for preventing the base interconnection substrate from deforming in a transfer mold process, a semiconductor chip mounted on a second surface of the base interconnection substrate, and a resin portion encapsulating or sealing the semiconductor chip.

The reinforcing member provided as described above can support, in the transfer mold process, a part of the base interconnection substrate that has no electrode pad. Accordingly, the base interconnection substrate can be prevented from deforming in the transfer mold process.

The base interconnection substrate includes a through hole and a conductor portion formed in the through hole. Preferably, the electrode pad is arranged on or near the through hole to be connected electrically to the conductor portion, and the reinforcing member is arranged on a region where no through hole is formed.

The reinforcing member having no function of the electrode is provided in the region where the electrode pad is not formed so that both of the electrode pad and reinforcing member can be used to support the base interconnection substrate in the transfer mold process to achieve the advantage as described above.

Preferably, a solder ball is formed on the electrode pad and the reinforcing member is covered with an insulating layer. In this way, the solder ball can be used to connect the electrode pad to an electrode or the like on a mounting substrate. The reinforcing member here can be protected by being covered with the insulating layer.

The semiconductor device is mounted on a mounting substrate having a land. In this case, the electrode pad and the land are electrically connected via the solder ball, and the reinforcing member is separated from the mounting substrate without connecting to the land.

Preferably, the reinforcing member and the electrode pad are formed of the same material. Then, the reinforcing member and electrode pad can be produced in the same process to simplify the entire manufacturing process.

A method of manufacturing a semiconductor device according to the present invention includes the steps of forming an interconnect portion on a base interconnection substrate formed of an insulating material, forming an electrode pad for external connection on a first surface of the base interconnection substrate to electrically connect to the interconnect portion, forming a reinforcing member on the first surface for preventing the base interconnection substrate from deforming in a transfer mold process, mounting a semiconductor chip on a second surface of the base interconnection substrate, and forming a resin portion by a transfer mold method to encapsulate the semiconductor chip.

In this way, the reinforcing member is fabricated in addition to the electrode pad to support the base interconnection substrate by the reinforcing member and electrode pad in the transfer mold process. It is thus possible to prevent deformation of the base interconnection substrate in the transfer mold process.

Preferably, the method of manufacturing a semiconductor device according to the present invention further includes the steps of forming a through hole in the base interconnection substrate and forming a conductor portion in the through hole. The step of forming the electrode pad includes the step of forming the electrode pad on or near the through hole to electrically connect to the conductor portion, and the step of forming the reinforcing member includes the step of forming the reinforcing member on a region where no through hole is formed.

The step of forming the resin portion includes the step of forming the resin portion in a metal mold to contain the reinforcing member and the electrode pad supporting the base interconnection substrate. Then, deformation of the base interconnection substrate can be avoided in the transfer mold process.

A base interconnection substrate according to the present invention includes a base formed of an insulating material, an interconnect portion formed on the base, an electrode pad for external connection formed on a first surface of the base and connected to the interconnect portion, and a reinforcing member formed on the first surface for preventing the base from deforming in a transfer mold process.

The electrode pad and reinforcing member thus fabricated can prevent the base from deforming in the transfer mold process. As a result, it is possible to prevent a semiconductor chip mounted on the base interconnection substrate from being damaged in the transfer mold process.

The base interconnection substrate includes a though hole and a conductor portion formed in the through hole. In this case, the electrode pad is arranged on or near the through hole to electrically connect to the conductor portion, and the reinforcing member is formed on a region where no through hole is formed.

A method of manufacturing a base interconnection substrate according to the present invention includes the steps of forming an interconnect portion on a base formed of an insulating material, forming an electrode pad for external connection on a first surface of the base to electrically connect to the interconnect portion, and forming a reinforcing member on the first surface for preventing the base from deforming in a transfer mold process.

The base interconnection substrate can accordingly be manufactured including the electrode pad and the reinforcing member to prevent the interconnection substrate from deforming in the transfer mold process. Then, a semiconductor chip mounted on the base interconnection substrate can be prevented from being damaged in the transfer mold process.

The method of manufacturing a base interconnection substrate according to the invention may further include the steps of forming a through hole in the base and forming a conductor portion in the through hole. In this case, the step of forming the electrode pad includes the step of forming the electrode pad on or near the through hole to electrically connect to the conductor portion, and the step of forming the reinforcing member includes the step of forming the reinforcing member on a region where no through hole is formed.

Further, the method of manufacturing a base interconnection substrate according to the invention may include the steps of forming an insulating layer to cover the electrode pad and the reinforcing member, and removing the insulating layer on the electrode pad. The removal of the insulating layer on the electrode pad allows a conductive layer for external connection to be formed on the electrode pad while the reinforcing member can be protected by the insulating layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of a semiconductor device according to a first embodiment of the present invention.

FIG. 2 is a plan view of the semiconductor device shown in FIG. 1.

FIG. 3 shows a cross section of a conventional semiconductor device at a transfer mold step of a manufacturing process of the semiconductor device.

FIG. 4 shows a cross section of a semiconductor device according to the present invention at a transfer mold step of a manufacturing process of the semiconductor device.

FIG. 5 shows a modified model of a conventional resin frame (base interconnection substrate).

FIG. 6 shows a modified model of a resin frame (base interconnection substrate) according to the present invention.

FIG. 7 shows a cross section of the semiconductor device mounted on a mounting substrate according to the first embodiment.

FIG. 8 illustrates a manufacturing process of a base interconnection substrate according to the present invention.

FIG. 9 is a cross sectional view of a semiconductor device according to a second embodiment of the present invention.

FIG. 10 is a plan view of the semiconductor device shown in FIG. 9.

FIG. 11 is a plan view of a modification of the semiconductor device in the second embodiment.

FIG. 12 is a plan view of another modification of the semiconductor device in the second embodiment.

FIG. 13 is a plan view of still another modification of the semiconductor device in the second embodiment.

### DESCRIPTION OF THE PREFERRED EMBODIMENTS

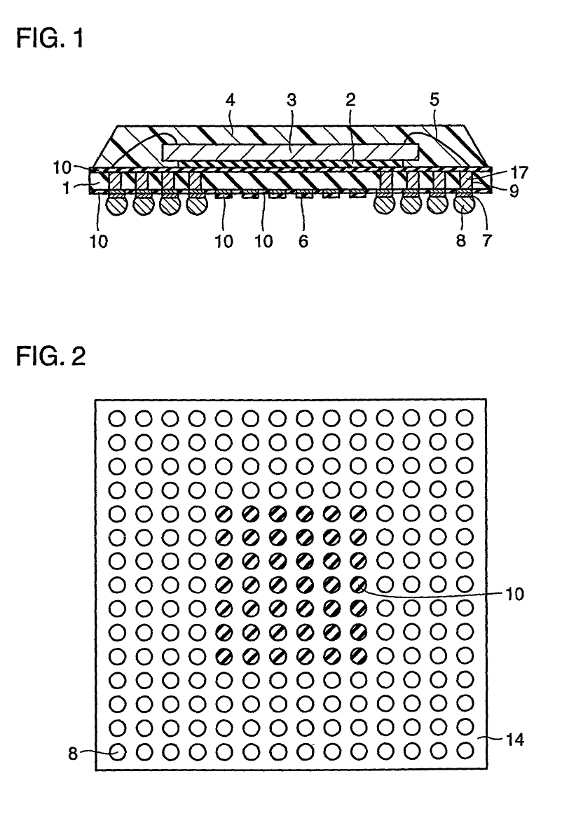

The present invention has a principal characteristic that a reinforcing structure is provided to a base interconnection substrate in order to prevent the base interconnection substrate from deforming in a transfer mold process due to the injection pressure of mold resin. Embodiments of the present invention are hereinafter described in conjunction with FIGS. 1 to 11.

### FIRST EMBODIMENT

FIG. 1 is a cross sectional view of a semiconductor device (package) according to a first embodiment of the present invention and FIG. 2 is a plan view thereof to show a mounting plane 14 of the semiconductor device.

Referring to FIGS. 1 and 2, the semiconductor device of the first embodiment is of a surface mount type including a base interconnection substrate 1, an IC chip 3 and a mold resin portion 4.

Base interconnection substrate 1 includes a base formed of an insulating material, electrode pads 7 and reinforcing pads 6 on mounting plane 14, through holes 9 and an interconnect portion (including land).

Reinforcing pads 6 formed of metal such as copper are arranged in the form of a matrix on the central part of mounting plane 14 of base interconnection substrate 1. Reinforcing pads 6 are provided separately and not electrically connected to the interconnect portion.

An insulating layer like a solder resist 10 is formed on reinforcing pads 6 as well as between the pads. Solder resist 10 has a coefficient of elasticity smaller than that of reinforcing pads 6.

Electrode pads 7 are formed on the peripheral region of mounting plane 14 of base interconnection substrate 1. According to the embodiment shown in FIG. 1, electrode pads 7 have a stacked structure formed of a metal layer like copper and a conductive layer formed thereon such as a solder layer. However, electrode pads 7 may be formed of a metal layer only. Electrode pads 7 are electrically connected to the interconnect portion to constitute a part of external connection terminals.

Solder balls 8 are formed on electrode pads 7. Although solder balls 8 are formed on the conductive layer mentioned above according to the embodiment shown in FIG. 1, solder balls 8 may directly be formed on the metal layer if no conductive layer is employed. The semiconductor device of the present invention is connected to a mounting substrate via solder balls 8. In other words, solder balls 8 serve as external connection terminals together with electrode pads 7.

FIG. 7 shows the semiconductor device of the present invention that is mounted on a mounting substrate 15. As shown in FIG. 7, lands 16 formed on mounting substrate 15 and electrode pads 7 are connected via solder balls 8. Reinforcing pads 6 are not connected to lands 16 on mounting substrate 15 in this state.

Referring again to FIG. 1, conductor portion 17 is formed in through hole 9 to constitute a part of the interconnect portion. The interconnect portion is formed not only on mounting plane 14 of base interconnection substrate 1 but also on a plane of base interconnection substrate 1 on which IC chip 3 is mounted.

A land for wire connection (not shown) is formed on the plane on which IC chip 3 is mounted. The wire connection land and a bonding pad (not shown) of IC chip 3 are connected via Au wire 5.

IC chip 3 is mounted on base interconnection substrate 1 via a die bonding material 2 and connected via Au wire 5 to the wire connection land. IC chip 3 is encapsulated by mold resin portion 4.

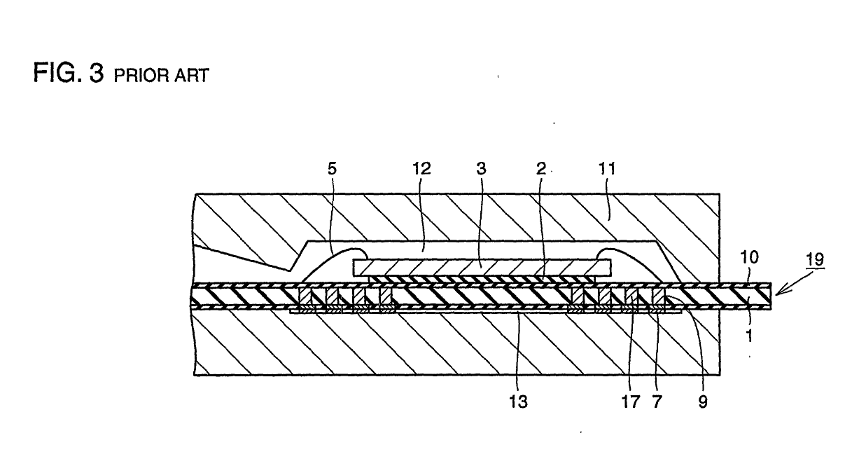

Referring to FIGS. 3 to 6, advantages achieved by providing reinforcing pads 6 of the present invention are described.

In the conventional semiconductor device shown in FIG. 3, gap 13 is present under the central region of resin frame 19 located in cavity 12 as described above. Then, at a transfer mold step, the injection pressure of mold resin causes resin frame 19 to deform resulting in damage to IC chip 3.

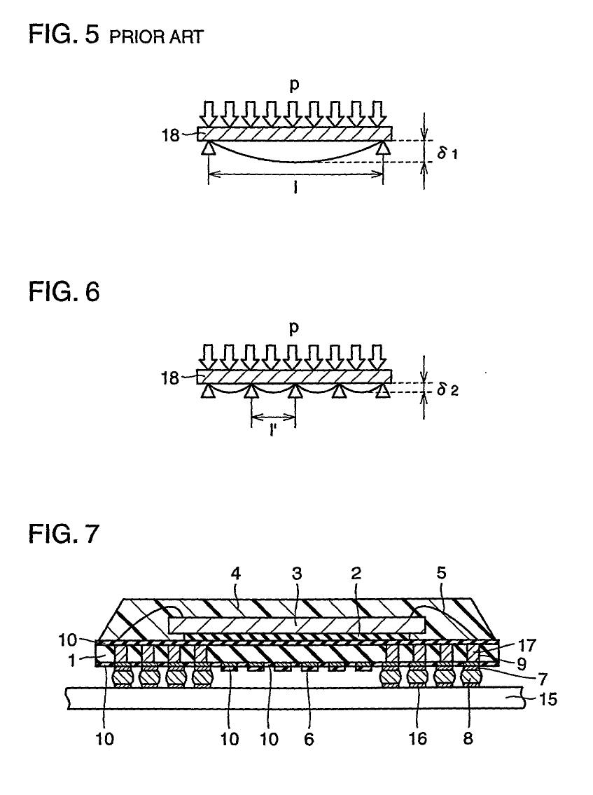

At the conventional transfer mold step shown in FIG. 3, the injection pressure of mold resin is exerted on resin frame 19. This state can be made approximate to a model as shown in FIG. 5 where a load with even distribution (total load pl) corresponding to charging pressure P is applied on a beam 18.

In this case, amount of flexure δ₁ of resin frame 19 is (5pl⁴) / (28EI) where E represents a coefficient of elasticity and I represents a moment of inertia of area.

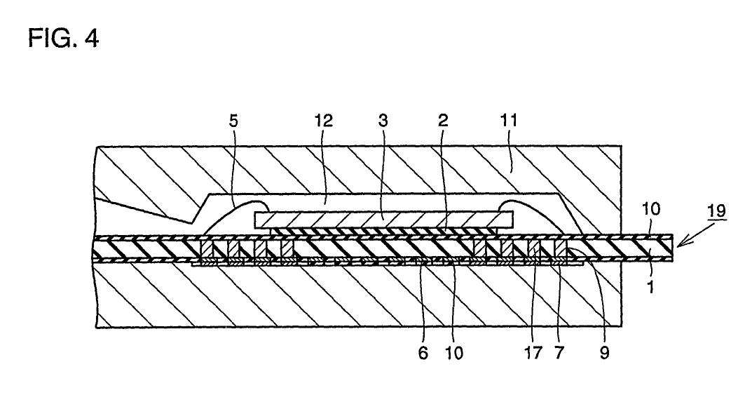

On the other hand, according to the invention shown in FIG. 4, reinforcing pads 6 provided on the central part of resin frame 19 which is placed in cavity 12 can support the central part of resin frame 19 at a transfer mold step.

Accordingly, even if a pressure from mold resin at the transfer mold step is applied on resin frame 19 and IC chip 3, resin frame 19 can be prevented from deforming.

FIG. 6 shows a model corresponding to the present invention. As shown in FIG. 6, reinforcing pads 6 of the present invention can be provided to increase the number of points which support resin frame 19 in cavity 12.

In the model shown in FIG. 6, span 1 is divided into four sections and accordingly three supporting points are provided. Alternatively, the state shown in FIG. 6 can be implemented by providing three reinforcing pads 6 at even intervals between the innermost electrode pads 7 for example. In this case, span 1′ between two supporting points is a quarter of span 1 shown in FIG. 5 and thus amount of flexure δ₂ of resin frame 19 is (5p14) / (7168EI).

In this way, the amount of flexure of resin frame 19 can dramatically be decreased as compared with that of the conventional semiconductor device. As a result, it is possible to avoid deformation of base interconnection substrate 1 produced by dividing resin frame 19. Distortion of IC chip 3 can thus be decreased and damage to IC chip 3 can effectively be prevented.

The position and shape of reinforcing pads 6 can readily be determined from the injection pressure and the amount of flexure of resin frame 19.

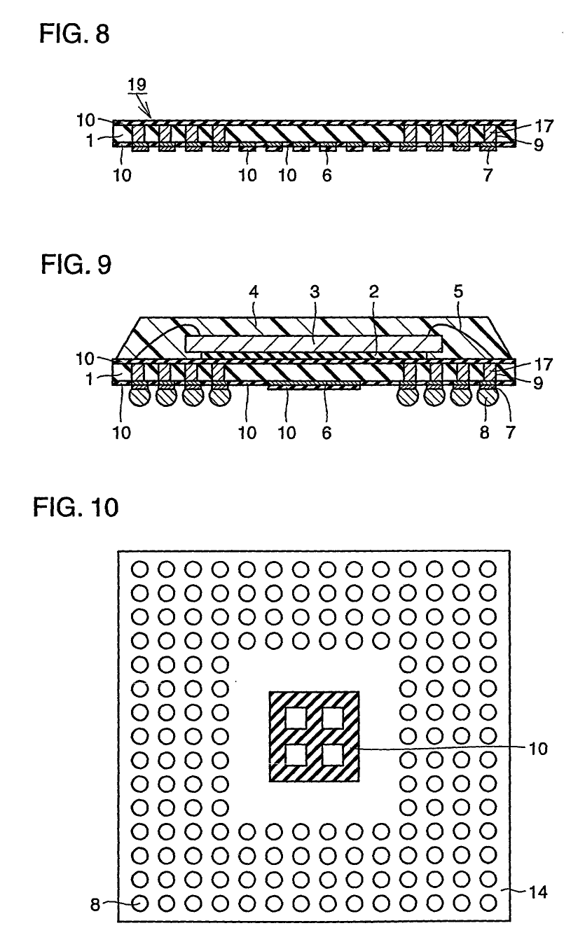

A method of manufacturing base interconnection substrate 1 according to the present invention is described below in conjunction with FIG. 8.

The base of base interconnection substrate 1 according to the invention is constituted of cloth of glass fiber or organic fiber and thermosetting resin. The thermosetting resin is selected as appropriate to meet required physical properties of the substrate from epoxy resin, bismaleimide resin, triazin resin, polyphenylene ether resin, denatured polyimide resin and the like.

The base (resin frame) formed of the materials as described above is fabricated and interconnection patterns are formed respectively on the plane on which IC chip 3 is mounted (IC mount plane) and on mounting plane 14. Then, through hole 9 is formed in the base to form conductor portion 17 in through hole 9. Respective interconnection patterns on the IC mount plane and mounting plane 14 are accordingly connected via conductor portion 17.

A metal layer of copper or the like is formed on mounting plane 14. The metal layer is patterned to form reinforcing pad 6 and electrode pad 7. Solder resists 10 are thereafter formed respectively on the IC mount plane and mounting plane 14 and the part of solder resist 10 on electrode pad 7 is removed.

On electrode pad 7 with solder resist 10 removed therefrom, a conductive layer such as a solder layer is formed through plating or screen printing. Accordingly, an electrode terminal on which a solder ball is mounted is formed.

Although reinforcing pad 6 may be formed after the fabrication of electrode pad 7, those pads can simultaneously be formed to allow reinforcing pad 6 and electrode pad 7 to have the same thickness and enable simple and low-cost fabrication of reinforcing pad 6. Reinforcing pad 6 may be adhered onto mounting plane 14.

A method of manufacturing the semiconductor device according to the present invention is described below in conjunction with FIG. 4.

At a predetermined position on resin frame 19 (see FIG. 4) produced by the method as discussed above, IC chip 3 is adhered by means of die bonding material 2 such as a bonding film or bonding paste.

Then, by wire bonding, a bonding pad (joint terminal) on IC chip 3 and a land (internal terminal) on base interconnection substrate 1 are electrically connected by Au wire 5 (see FIG. 4).

After this, metal molds 11 are used as shown in FIG. 4 to encapsulate IC chip 3 in resin through a transfer mold process. It is important at this time that electrode pad 7 and solder resist 10 on reinforcing pad 6 uniformly contact the surface of metal mold 11 as shown in FIG. 4.

After the mold process as described above, baking is performed to mount solder ball 8 as shown in FIG. 1 on electrode pad 7. Resin frame 19 is divided into pieces to produce semiconductor devices, FIG. 1 showing one of such semiconductor devices.

### SECOND EMBODIMENT

Referring to FIGS. 9 to 13, a second embodiment and modifications thereof are described. FIG. 9 is a cross sectional view of a semiconductor device according to the second embodiment. FIG. 10 is a plan view of the semiconductor device in FIG. 9 to show a mounting plane 14.

According to the second embodiment, a reinforcing pad 6 has its shape different from that in the first embodiment as shown in FIGS. 9 and 10. Specifically, a large one-piece reinforcing pad 6 in the shape of a grid is formed. Other structural components are similar to those of the first embodiment and description thereof is not repeated here.

Like reinforcing pad 6 of the first embodiment, reinforcing pad 6 of the second embodiment can support a resin frame 19 (base interconnection substrate 1) in the transfer mold process and thus it is possible to prevent deformation of resin frame 19 (base interconnection substrate 1) due to the injection pressure of mold resin.

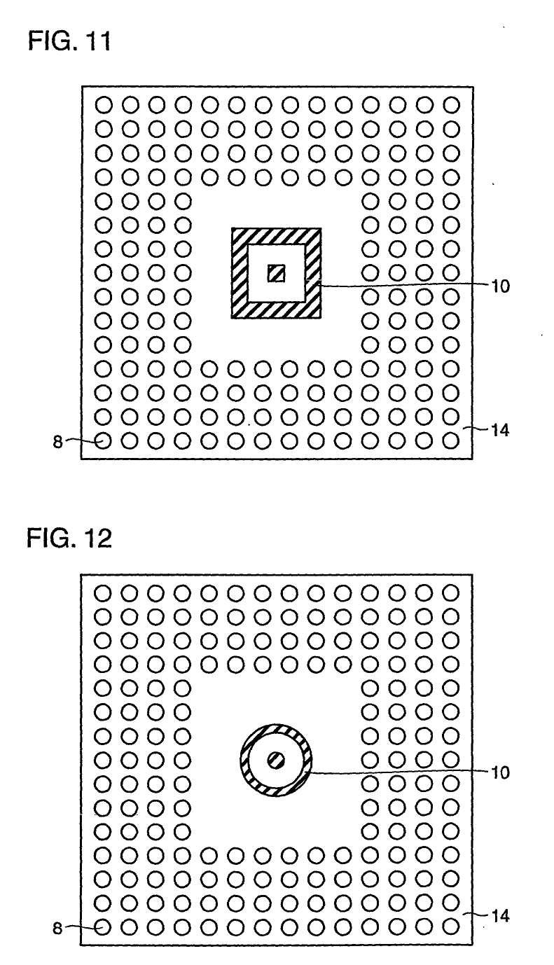

Modifications of the second embodiment are described in conjunction with FIGS. 11 to 13.

Referring to FIGS. 11 and 12, a reinforcing pad 6 in the shape of a ring may be formed and a further reinforcing pad 6 may be formed therein. Reinforcing pads 6 can also support resin frame 19 (base interconnection substrate 1) in the transfer mold process.

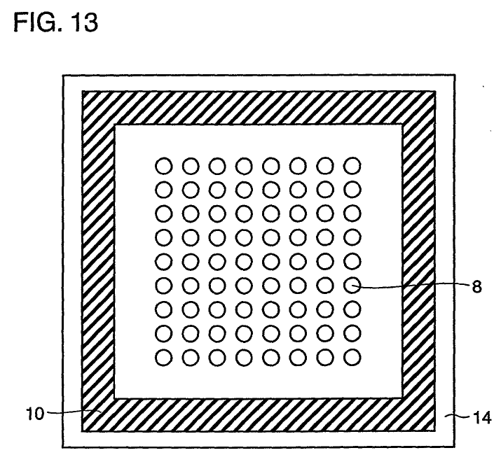

As shown in FIG. 13, electrode pads 7 may be arranged in the central region of base interconnection substrate 1 and a reinforcing pad 6 may be arranged in the peripheral region of base interconnection substrate 1. This reinforcing pad 6 can also support resin frame 19 (base interconnection substrate 1) in the transfer mold process.

In particular, reinforcing pad 6 shown in FIG. 13 is useful when IC chip 3 extends outward relative to electrode pads 7. Although the example shown in FIG. 13 is provided to include one-piece reinforcing pad 6 in the shape of a frame, a plurality of reinforcing pads 6 may alternatively be arranged along the peripheral region of base interconnection substrate 1.

The shape and material of reinforcing pad 6 may arbitrarily be selected as any which can support resin frame 19 (base interconnection substrate 1) together with electrode pad 7 in the process of transfer molding to prevent resin frame 19 (base interconnection substrate 1) from deforming in the transfer mold process.

Moreover, reinforcing pad 6 may be formed of any material different from that of electrode pad 7. In this case, the material of reinforcing pad 6 is preferably selected to have a coefficient of elasticity almost equal to that of electrode pad 7.

The present invention is particularly useful for a semiconductor device having an electrode pad 7 of at least 5 μm in thickness.

According to the present invention, it is possible to prevent the base interconnection substrate (resin frame) from deforming in the transfer mold process and thus to prevent the semiconductor chip from being damaged due to deformation of the base interconnection substrate. As a result, the reliability of the semiconductor device can be improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a base interconnection substrate having an interconnect portion;
an electrode pad for external connection formed on a first surface of said base interconnection substrate and connected to said interconnect portion;
a reinforcing member formed on said first surface for preventing said base interconnection substrate from deforming in a transfer mold process;
a semiconductor chip mounted on a second surface of said base interconnection substrate; and
a resin portion encapsulating said semiconductor chip.

2. The semiconductor device according to claim 1, wherein
said base interconnection substrate includes a through hole and a conductor portion formed in said through hole,
said electrode pad is arranged on or near said through hole to be connected electrically to said conductor portion, and
said reinforcing member is arranged on a region where no through hole is formed.

3. The semiconductor device according to claim 1, wherein
a solder ball is formed on said electrode pad and said reinforcing member is covered with an insulating layer.

4. The semiconductor device according to claim 3, wherein
said semiconductor device is mounted on a mounting substrate having a land,
said electrode pad and said land are electrically connected via said solder ball, and
said reinforcing member is separated from said mounting substrate without connecting to said land.

5. The semiconductor device according to claim 1, wherein
said reinforcing member and said electrode pad are formed of the same material.

6. A method of manufacturing a semiconductor device comprising the steps of:
forming an interconnect portion on a base interconnection substrate formed of an insulating material;
forming an electrode pad for external connection on a first surface of said base interconnection substrate to electrically connect to said interconnect portion;
forming a reinforcing member on said first surface for preventing said base interconnection substrate from deforming in a transfer mold process;
mounting a semiconductor chip on a second surface of said base interconnection substrate; and
forming a resin portion by a transfer mold method to encapsulate said semiconductor chip.

7. The method of manufacturing a semiconductor device according to claim 6, further comprising the steps of
forming a through hole in said base interconnection substrate and
forming a conductor portion in said through hole, wherein
said step of forming said electrode pad includes the step of forming said electrode pad on or near said through hole to electrically connect to said conductor portion, and
said step of forming said reinforcing member includes the step of forming said reinforcing member on a region where no through hole is formed.

8. The method of manufacturing a semiconductor device according to claim 6, wherein
said step of forming said resin portion includes the step of forming said resin portion in a metal mold with said reinforcing member and said electrode pad supporting said base interconnection substrate.

9. A base interconnection substrate comprising:
a base formed of an insulating material;
an interconnect portion formed on said base;
an electrode pad for external connection formed on a first surface of said base and connected to said interconnect portion; and
a reinforcing member formed on said first surface for preventing said base from deforming in a transfer mold process.

10. The base interconnection substrate according to claim 9, further comprising a though hole and a conductor portion formed in said through hole, wherein
said electrode pad is arranged on or near said through hole to electrically connect to said conductor portion, and
said reinforcing member is formed on a region where no through hole is formed.
